(19) United States
(12) Patent Application Publication
(10) Pub. No.: US 2022/0392745 A1
(43) Pub. Date: Dec. 8, 2022

(54) INSPECTION APPARATUS

(71) Applicant: ASML Netherlands B.V., Veldhoven (NL)

(72) Inventor: Marco Jan-Jaco WIELAND, Delft (NL)

(73) Assignee: ASML Netherlands B.V., Veldhoven (NL)

(21) Appl. No.: 17/891,961

(22) Filed: Aug. 19, 2022

Related U.S. Application Data
(63) Continuation of application No. PCT/EP2021/053325, filed on Feb. 11, 2021.

(30) Foreign Application Priority Data
Feb. 21, 2020 (EP) 20158863.9
Jul. 6, 2020 (EP) 20184162.4
Nov. 11, 2020 (EP) 20206987.8

(51) Int. Cl. H01J 37/317; H01J 37/12; H01J 37/153

(52) U.S. Cl. CPC H01J 37/3177; H01J 37/12; H01J 37/153; H01J 2237/1534

(57) ABSTRACT

A charged-particle assessment tool comprising a plurality of beam columns. Each beam column comprises: a charged-particle beam source configured to emit charged particles; a plurality of condenser lenses configured to form charged particles emitted from the charged-particle beam source into a plurality of charged-particle beams; and a plurality of objective lenses, each configured to project one of the plurality of charged-particle beams onto a sample. The beam columns are arranged adjacent one-another so as to project the charged particle beams onto adjacent regions of the sample.

### CROSS-REFERENCE TO RELATED APPLICATIONS

This application claims priority of International application PCT/EP2021/053325, which was filed on 11 Feb. 2021, which claims priority of EP application 20158863.9, which was filed on 21 Feb. 2020, of EP application 20184162.4, which was filed on 6 Jul. 2020, and of EP application 20206987.8, which was filed on 11 Nov. 2020, all of which are each incorporated herein by reference in their entireties.

### FIELD

The embodiments provided herein generally relate to a charged particle assessment tools and inspection methods, and particularly to charged particle assessment tools and inspection methods that use multiple sub-beams of charged particles.

### BACKGROUND

When manufacturing semiconductor integrated circuit (IC) chips, undesired pattern defects, as a consequence of, for example, optical effects and incidental particles, inevitably occur on a substrate (i.e., wafer) or a mask during the fabrication processes, thereby reducing the yield. Monitoring the extent of the undesired pattern defects is therefore an important process in the manufacture of IC chips. More generally, the inspection and/or measurement of a surface of a substrate, or other object/material, is an important process during and/or after its manufacture.

Pattern inspection tools with a charged particle beam have been used to inspect objects, for example to detect pattern defects. These tools typically use electron microscopy techniques, such as a scanning electron microscope (SEM). In a SEM, a primary electron beam of electrons at a relatively high energy is targeted with a final deceleration step in order to land on a sample at a relatively low landing energy. The beam of electrons is focused as a probing spot on the sample. The interactions between the material structure at the probing spot and the landing electrons from the beam of electrons cause electrons to be emitted from the surface, such as secondary electrons, backscattered electrons, or Auger electrons. The generated secondary electrons may be emitted from the material structure of the sample. By scanning the primary electron beam as the probing spot over the sample surface, secondary electrons can be emitted across the surface of the sample. By collecting these emitted secondary electrons from the sample surface, a pattern inspection tool may obtain an image representing characteristics of the material structure of the surface of the sample.

There is a general need to improve the throughput and other characteristics of a charged particle inspection apparatus.

### SUMMARY

The embodiments provided herein disclose a charged particle beam inspection apparatus.

According to some embodiments of the present disclosure, there is provided a charged-particle assessment tool comprising:

a plurality of beam columns, each beam column comprising: a charged-particle beam source configured to emit charged particles; a plurality of condenser lenses configured to form charged particles emitted from the charged-particle beam source into a plurality of charged-particle beams; and a plurality of objective lenses, each configured to project one of the plurality of charged-particle beams onto a sample; wherein:

the beam columns are arranged adjacent one-another so as to project the charged particle beams onto adjacent regions of the sample.

According to some embodiments of the present disclosure, there is provided an inspection method comprising:

using a plurality of beam columns to emit charged-particle beams toward a sample, each beam column comprising: a charged-particle beam source configured to emit charged particles; a plurality of condenser lenses configured to form charged particles emitted from the charged-particle beam source into a plurality of charged-particle beams; and a plurality of objective lenses, each configured to project one of the plurality of charged-particle beams onto the sample; wherein:

the beam columns are arranged adjacent one-another so as to project the charged particle beams onto adjacent regions of the sample.

According to some embodiments of the present disclosure, there is provided a charged-particle multi-beam column array for a charged-particle tool for projecting a plurality of charged-particle multi-beams towards a sample, the charged-particle multi-beam column array comprising:

a plurality of charged-particle multi-beam columns configured to project respective multi-beams simultaneously onto different regions of the sample; and

a focus corrector configured to apply a group focus correction to each of a plurality of groups of sub-beams of the multi-beams, each group focus correction being the same for all of the sub-beams of the respective group.

According to some embodiments of the present disclosure, there is provided an inspection method, comprising:

using a multi-beam column array to project plural charged-particle multi-beams towards a sample; and

applying a group focus correction to each of a plurality of groups of sub-beams of the multi-beams, each group focus correction being the same for all of the sub-beams of the respective group.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an exemplary charged particle beam inspection apparatus.

FIG. 2 is a schematic diagram illustrating an exemplary multi-beam apparatus that is part of the exemplary charged particle beam inspection apparatus of FIG. 1.

FIG. 3 is a schematic diagram of exemplary multi-beam apparatus, according to some embodiments of the present disclosure.

FIG. 4 is a schematic diagram of another exemplary multi-beam apparatus, according to some embodiments of the present disclosure.

FIG. 5 is a graph of landing energy vs. spot size.

FIG. 6 is an enlarged diagram of an objective lens, according to some embodiments of the present disclosure.

FIG. 7 is a schematic cross-sectional view of an objective lens of an inspection apparatus, according to some embodiments of the present disclosure.

FIG. 8 is bottom view of the objective lens of FIG. 7.

FIG. 9 is a bottom view of a modification of the objective lens of FIG. 7.

FIG. 10 is an enlarged schematic cross-sectional view of a detector incorporated in the objective lens of FIG. 7.

FIG. 11 is a schematic side view of an inspection tool having multiple adjacent optical columns.

FIG. 12 is a schematic plan view of an inspection tool having multiple adjacent optical columns in a rectangular arrangement.

FIG. 13 is a schematic plan view of an inspection tool having multiple adjacent optical columns in a hexagonal arrangement.

FIG. 14 is a schematic side sectional view of a corrector aperture array integrated with an objective lens array comprising two electrodes.

FIG. 15 is a schematic side section view of a corrector aperture array integrated with an objective lens array comprising three electrodes.

FIG. 16 is a schematic top view of electrodes in an example corrector aperture array, the electrodes comprising relatively wide elongate conductive strips aligned in a first direction.

FIG. 17 is a schematic top view of electrodes in a further example corrector aperture array, the electrodes comprising relatively wide elongate conductive strips aligned in a second direction.

FIG. 18 is a schematic top view of electrodes in a further example corrector aperture array, the electrodes comprising relatively narrow elongate conductive strips aligned in the first direction.

FIG. 19 is a schematic top view of electrodes in a further example corrector aperture array, the electrodes comprising relatively narrow elongate conductive strips aligned in the second direction.

FIG. 20 is a schematic top view of electrodes of a further example corrector aperture array, the electrodes comprising lower aspect ratio, tessellating conductive elements.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims.

The enhanced computing power of electronic devices, which reduces the physical size of the devices, can be accomplished by significantly increasing the packing density of circuit components such as transistors, capacitors, diodes, etc. on an IC chip. This has been enabled by increased resolution enabling yet smaller structures to be made. For example, an IC chip of a smart phone, which is the size of a thumbnail and available in, or earlier than, 2019, may include over 2 billion transistors, the size of each transistor being less than 1/1000th of a human hair. Thus, it is not surprising that semiconductor IC manufacturing is a complex and time-consuming process, with hundreds of individual steps. Errors in even one step have the potential to dramatically affect the functioning of the final product. Just one “killer defect” can cause device failure. The goal of the manufacturing process is to improve the overall yield of the process. For example, to obtain a 75% yield for a 50-step process (where a step can indicate the number of layers formed on a wafer), each individual step must have a yield greater than 99.4%. If each individual step had a yield of 95%, the overall process yield would be as low as 7%.

While high process yield is desirable in an IC chip manufacturing facility, maintaining a high substrate (i.e., wafer) throughput, defined as the number of substrates processed per hour, is also essential. High process yield and high substrate throughput can be impacted by the presence of a defect. This is especially if operator intervention is required for reviewing the defects. Thus, high throughput detection and identification of micro and nano-scale defects by inspection tools (such as a Scanning Electron Microscope (SEW)) is essential for maintaining high yield and low cost.

A SEM comprises a scanning device and a detector apparatus. The scanning device comprises an illumination apparatus that comprises an electron source and a projection apparatus. The electron source is for generating primary electrons. The projection apparatus is for scanning a sample, such as a substrate, with one or more focused beams of primary electrons. Together at least the illumination apparatus, or illumination system, and the projection apparatus, or projection system, may be referred to together as the electron-optical system or apparatus. The primary electrons interact with the sample and generate secondary electrons. The detection apparatus captures the secondary electrons from the sample as the sample is scanned so that the SEM can create an image of the scanned area of the sample. For high throughput inspection, some of the inspection apparatuses use multiple focused beams, i.e., a multi-beam, of primary electrons. The component beams of the multi-beam may be referred to as sub-beams or beamlets. A multi-beam can scan different parts of a sample simultaneously. A multi-beam inspection apparatus can therefore inspect a sample at a much higher speed than a single-beam inspection apparatus.

An implementation of a known multi-beam inspection apparatus is described below.

The figures are schematic. Relative dimensions of components in drawings are therefore exaggerated for clarity. Within the following description of drawings, the same or like reference numbers refer to the same or like components or entities, and only the differences with respect to the individual embodiments are described. While the description and drawings are directed to an electron-optical apparatus, it is appreciated that the embodiments are not used to limit the present disclosure to specific charged particles. References to electrons throughout the present document may therefore be more generally be considered to be references to charged particles, with the charged particles not necessarily being electrons.

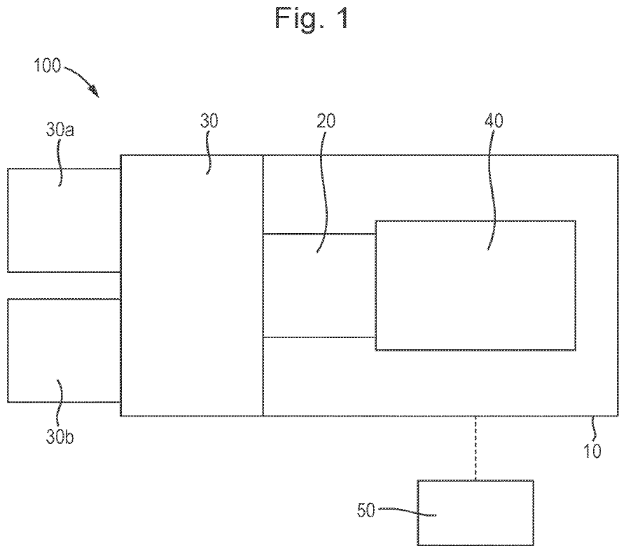

Reference is now made to FIG. 1, which is a schematic diagram illustrating an exemplary charged particle beam inspection apparatus 100. The charged particle beam inspection apparatus 100 of FIG. 1 includes a main chamber 10, a load lock chamber 20, an electron beam tool 40, an equipment front end module (EFEM) 30 and a controller 50. Electron beam tool 40 is located within main chamber 10.

EFEM 30 includes a first loading port 30a and a second loading port 30b. EFEM 30 may include additional loading port(s). First loading port 30a and second loading port 30b may, for example, receive substrate front opening unified pods (FOUPs). A FOUP contains a substrate (e.g., a semiconductor substrate or a substrate made of other material(s)) or a sample to be inspected (substrates, wafers and samples are collectively referred to as “samples” hereafter). One or more robot arms (not shown) in EFEM 30 transport the samples to load lock chamber 20.

Load lock chamber 20 is used to remove the gas around a sample. This creates a vacuum that is a local gas pressure lower than the pressure in the surrounding environment. The load lock chamber 20 may be connected to a load lock vacuum pump system (not shown), which removes gas particles in the load lock chamber 20. The operation of the load lock vacuum pump system enables the load lock chamber to reach a first pressure below the atmospheric pressure. After reaching the first pressure, one or more robot arms (not shown) transport the sample from load lock chamber 20 to main chamber 10. Main chamber 10 is connected to a main chamber vacuum pump system (not shown). The main chamber vacuum pump system removes gas particles in main chamber 10 so that the pressure in around the sample reaches a second pressure lower than the first pressure. After reaching the second pressure, the sample is transported to the electron beam tool by which it may be inspected. An electron beam tool 40 may comprise a multi-beam electron-optical apparatus.

Controller 50 is electronically connected to electron beam tool 40. Controller 50 may be a processor (such as a computer) configured to control the charged particle beam inspection apparatus 100. Controller 50 may also include a processing circuitry configured to execute various signal and image processing functions. While controller 50 is shown in FIG. 1 as being outside of the structure that includes main chamber 10, load lock chamber 20, and EFEM 30, it is appreciated that controller 50 may be part of the structure. The controller 50 may be located in one of the component elements of the charged particle beam inspection apparatus or it can be distributed over at least two of the component elements. While the present disclosure provides examples of main chamber 10 housing an electron beam inspection tool, it should be noted that aspects of the disclosure in their broadest sense are not limited to a chamber housing an electron beam inspection tool. Rather, it is appreciated that the foregoing principles may also be applied to other tools and other arrangements of apparatus, that operate under the second pressure.

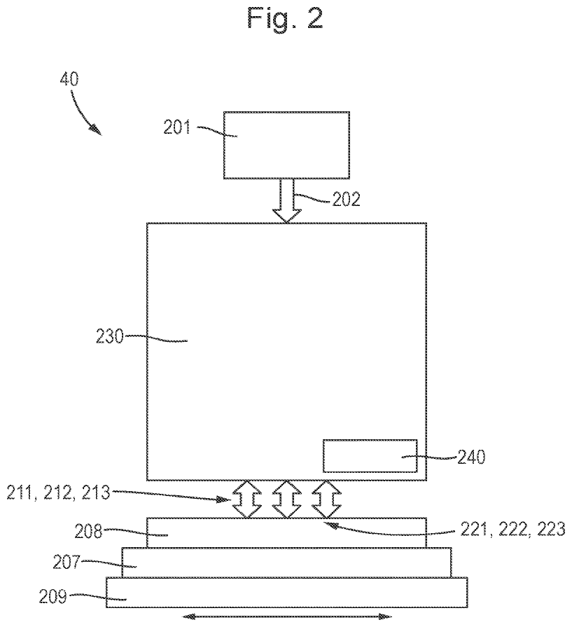

Reference is now made to FIG. 2, which is a schematic diagram illustrating an exemplary electron beam tool 40 including a multi-beam inspection tool that is part of the exemplary charged particle beam inspection apparatus 100 of FIG. 1. Multi-beam electron beam tool 40 (also referred to herein as apparatus 40) comprises an electron source 201, a projection apparatus 230, a motorized stage 209, and a sample holder 207. The electron source 201 and projection apparatus 230 may together be referred to as an electron-optical apparatus. The sample holder 207 is supported by motorized stage 209 so as to hold a sample 208 (e.g., a substrate or a mask) for inspection. Multi-beam electron beam tool 40 further comprises an electron detection device 240.

Electron source 201 may comprise a cathode (not shown) and an extractor or anode (not shown). During operation, electron source 201 is configured to emit electrons as primary electrons from the cathode. The primary electrons are extracted or accelerated by the extractor and/or the anode to form a primary electron beam 202.

Projection apparatus 230 is configured to convert primary electron beam 202 into a plurality of sub-beams 211, 212, 213 and to direct each sub-beam onto the sample 208. Although three sub-beams are illustrated for simplicity, there may be many tens, many hundreds or many thousands of sub-beams. The sub-beams may be referred to as beamlets.

Controller 50 may be connected to various parts of charged particle beam inspection apparatus 100 of FIG. 1, such as electron source 201, electron detection device 240, projection apparatus 230, and motorized stage 209. Controller 50 may perform various image and signal processing functions. Controller 50 may also generate various control signals to govern operations of the charged particle beam inspection apparatus, including the charged particle multi-beam apparatus.

Projection apparatus 230 may be configured to focus sub-beams 211, 212, and 213 onto a sample 208 for inspection and may form three probe spots 221, 222, and 223 on the surface of sample 208. Projection apparatus 230 may be configured to deflect primary sub-beams 211, 212, and 213 to scan probe spots 221, 222, and 223 across individual scanning areas in a section of the surface of sample 208. In response to incidence of primary sub-beams 211, 212, and 213 on probe spots 221, 222, and 223 on sample 208, electrons are generated from the sample 208 which include secondary electrons and backscattered electrons. The secondary electrons typically have electron energy≤50 eV. Backscattered electrons typically have electron energy between 50 eV and the landing energy of primary sub-beams 211, 212, and 213.

Electron detection device 240 is configured to detect secondary electrons and/or backscattered electrons and to generate corresponding signals which are sent to controller 50 or a signal processing system (not shown), e.g., to construct images of the corresponding scanned areas of sample 208. Electron detection device may be incorporated into the projection apparatus or may be separate therefrom, with a secondary optical column being provided to direct secondary electrons and/or backscattered electrons to the electron detection device.

The controller 50 may comprise image processing system that includes an image acquirer (not shown) and a storage device (not shown). For example, the controller may comprise a processor, computer, server, mainframe host, terminals, personal computer, any kind of mobile computing devices, and the like, or a combination thereof. The image acquirer may comprise at least part of the processing function of the controller. Thus, the image acquirer may comprise at least one or more processors. The image acquirer may be communicatively coupled to an electron detection device 240 of the apparatus 40 permitting signal communication, such as an electrical conductor, optical fiber cable, portable storage media, IR, Bluetooth, internet, wireless network, wireless radio, among others, or a combination thereof. The image acquirer may receive a signal from electron detection device 240, may process the data comprised in the signal and may construct an image therefrom. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. The storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

The image acquirer may acquire one or more images of a sample based on an imaging signal received from the electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time period. The multiple images may be stored in the storage. The controller 50 may be configured to perform image processing steps with the multiple images of the same location of sample 208.

The controller 50 may include measurement circuitry (e.g., analog-to-digital converters) to obtain a distribution of the detected secondary electrons. The electron distribution data, collected during a detection time window, can be used in combination with corresponding scan path data of each of primary sub-beams 211, 212, and 213 incident on the sample surface, to reconstruct images of the sample structures under inspection. The reconstructed images can be used to reveal various features of the internal or external structures of sample 208. The reconstructed images can thereby be used to reveal any defects that may exist in the sample.

The controller 50 may control motorized stage 209 to move sample 208 during inspection of sample 208. The controller 50 may enable motorized stage 209 to move sample 208 in a direction, preferably continuously, for example at a constant speed, at least during sample inspection. The controller 50 may control movement of the motorized stage 209 so that it changes the speed of the movement of the sample 208 dependent on various parameters. For example, the controller may control the stage speed (including its direction) depending on the characteristics of the inspection steps of scanning process.

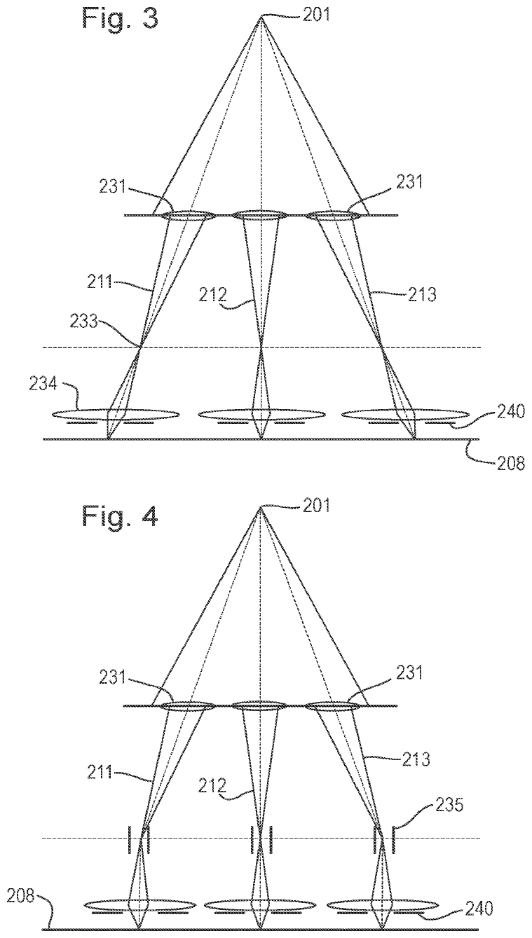

FIG. 3 is a schematic diagram of an inspection tool according to some embodiments of the present disclosure. Electron source 201 directs electrodes toward an array of condenser lenses 231 forming part of projection system 230. The electron source is desirably a high brightness thermal field emitter with a good compromise between brightness and total emission current. There may be many tens, many hundreds, or many thousands of condenser lenses 231. Condenser lenses are desirably Einzel lenses and may be constructed as described in EP1602121A1, which document is hereby incorporated by reference in particular to the disclosure of a lens array to split an e-beam into a plurality of multi-beams, with the array providing a lens for each beamlet. The lens array may take the form of at least two plates. The at least two plates act as electrodes. In each of the at least two plates is defined an aperture that are aligned with each other and corresponding to the location of a beamlet. Each plate is maintained during operation at a different potential to achieve the desired lensing effect. The lens array may comprise a beam limiting aperture array which may be one of the at least two plates.

In an arrangement the condenser lens array may be formed of three plate arrays in which the entrance and exit of lens has the same beam energy, which arrangement may be referred to as an Einzel lens. This is beneficial because off-axis chromatic aberrations are limited because dispersion only occurs within the Einzel lens. When the thickness of such a lens is of the order pf a few mm these aberrations are negligible.

Each condenser lens in the array directs electrons into a respective sub-beam 211, 212, 213 which is focused at a respective intermediate focus 233. The sub-beams diverge with respect to each other. Downbeam of the intermediate focuses 233 are a plurality of objective lenses 234, each of which directs a respective sub-beam 211, 212, 213 onto the sample 208. The objective lenses 234 may be Einzel lenses. At least the chromatic aberrations generated in a beam by a condenser lens and the corresponding down-beam objective lens may mutually cancel.

By controlling the landing energy of the electrons on the sample it is possible to control focus parameters and introduce other corrections. The landing energy can be selected to increase emission and detection of secondary electrons. A controller provided to control the objective lenses 234 may be configured to control the landing energy to any desired value within a predetermined range or to a desired one of a plurality of predetermined values. In some embodiments, the landing energy can be controlled to desired value in the range of from 1000 eV to 4000 eV or even 5000 eV.

An electron detection device 240 is provided between the objective lenses 234 and the sample 208 to detect secondary and/or backscattered electrons emitted from the sample 208. An exemplary construction of the electron detection system is described below.

In the system of FIG. 3, the beamlets 211, 212, 213 propagate along straight paths from the condenser lenses 231 to the sample 208. The beamlet paths diverge down beam of the condenser lenses 231. A variant construction is shown in FIG. 4 which is the same as the system of FIG. 3 except that deflectors 235 are provided at the intermediate focuses 233. The deflectors 235 are positioned in the beamlet paths at, or at least around, the position of the corresponding intermediate focusses 233 or focus points (i.e., points of focus). The deflectors are positioned in the beamlet paths at the intermediate image plane of the associated beamlet, i.e., at its focus or focus point. The deflectors 235 are configured to operate on the respective beamlets 211, 212, 213. Deflectors 235 are configured to bend a respective beamlet 211, 212, 213 by an amount effective to ensure that the principal ray (which may also be referred to as the beam axis) is incident on the sample 208 substantially normally (i.e., at substantially 90° to the nominal surface of the sample). Deflectors 235 may also be referred to as collimators or collimator deflectors. The deflectors 235 in effect collimate the paths of the beamlets so that before the deflectors, the beamlets paths with respect to each other are diverging. Down beam of the deflectors the beamlet paths are substantially parallel with respect to each other, i.e., substantially collimated. Thus, each beamlet path may be in a straight line between the array of condenser lenses 231 and the collimator e.g. the array of deflectors 235. Each beamlet path may be in a straight line between the array of deflectors 235 and the objective lens array 234 and optionally the sample 208. Suitable collimators are deflectors disclosed in EP Application 20156253.5 filed on 7 Feb. 2020 which is hereby incorporated by reference with respect to the application of the deflectors to a multi-beam array

The landing energy of the electrons may be more easily controlled in the system of FIG. 4 because any off-axis aberrations generated in the beamlet path are generated in, or at least mainly in, the condenser lenses 231. The objective lenses 234 of the system shown in FIG. 4 need not be Einzel lenses. This is because if the beams are collimated the off-axis aberrations would not be generated in the objective lenses. The off-axis aberrations can be controlled better in the condenser lenses than in the objective lenses 234. By making the condenser lenses 231 substantially thinner the contributions of the condenser lenses to the off-axis aberrations, specifically the chromatic off-axis aberrations, may be minimized. The thickness of the condenser lens 231 may be varied to tune the chromatic off-axis contribution balancing other contributions of the chromatic aberrations in the respective beamlet paths. Thus, the objective lenses 234 may have two or more electrodes. The beam energy on entering an objective lens can be different from its energy leaving the objective lens.

FIG. 6 is an enlarged schematic view of one objective lens 300 of the array of objective lenses in a three-electrode arrangement, such as an Einzel lens. Objective lens 300 can be configured to demagnify the electron beam by a factor greater than 10, desirably in the range of 50 to 100 or more. The objective lens comprises a middle or first electrode 301, a lower or second electrode 302 and an upper or third electrode 303. Voltage sources 351, 352, 353 are configured to apply potentials V1, V2, V3 to the first second and third electrodes respectively. A further voltage source is connected to the sample, to apply a fourth potential, which may be ground. Potentials can be defined relative to the sample 208. Desirably, in some embodiments, the third electrode is omitted. Such an arrangement is a two-electrode objective lens which may be used in the arrangement shown and described with respect to FIG. 4. The first, second and third electrodes are each provided with an aperture through which the respective sub-beam propagates. The second potential can be similar to the potential of the sample, e.g., about 50 V more positive. Alternatively, the second potential can be in the range of from about +500 V to about +1,500 V.

The first and/or second potentials can be varied per aperture to effect focus corrections.

To provide the objective lens 300 with a decelerating function, so that the landing energy can be determined, it is desirable to change the potential of the lowest electrode and the sample. To decelerate the electrons the lower (second) electrode is made more negative than the central electrode.

The highest electrostatic field strength occurs when the lowest landing energy is selected. The distance between the second electrode and middle electrode, lowest landing energy and maximum potential difference between second electrode and middle electrode are selected so that the resulting field strength is acceptable. For higher landing energies, the electrostatic field becomes lower (less deceleration over the same length).

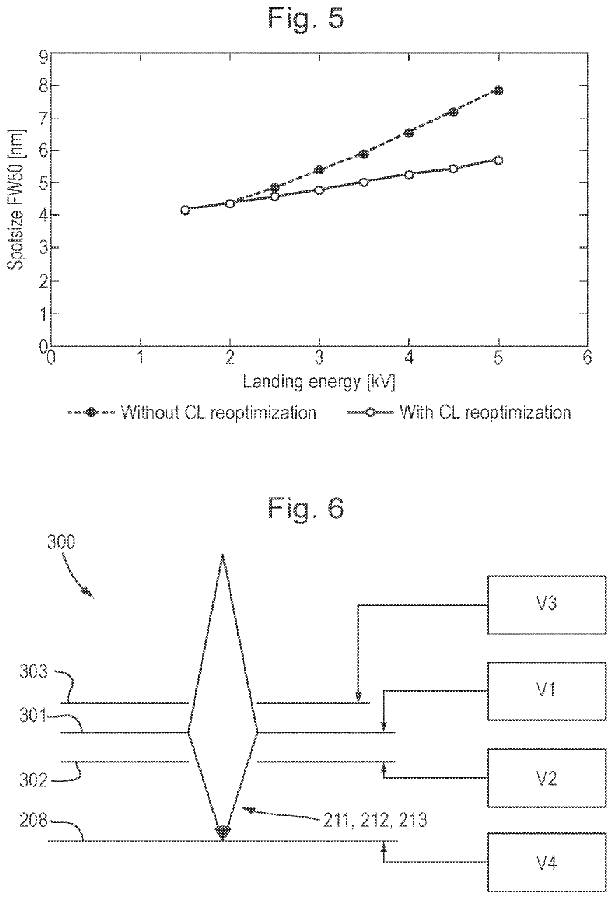

Because the electron optics configuration between the electron source and beam limiting aperture (just above the condenser lens) remain the same, the beam current remains unchanged with changes in landing energy. Changing the landing energy can affect resolution, either to improve or reduce it. FIG. 5 is a graph showing landing energy vs. spot size in two cases. The dashed line with solid circles indicates the effect of changing only the landing energy, i.e., the condenser lens voltage remains the same. The solid line with open circles indicates the effect if the landing energy is changed and condenser lens voltage (magnification versus opening angle optimization) is reoptimized.

If the condenser lens voltage is changed, the collimator will not be in the precise intermediate image plane for all landing energies. Therefore, it is desirable to correct the astigmatism induced by the collimator.

In some embodiments, the objective lens referred to in earlier embodiments is an array objective lens. Each element in the array is a micro-lens operating a different beam or group of beams in the multi-beam. An electrostatic array objective lens has at least two plates each with a plurality of holes or apertures. The position of each hole in a plate corresponds to the position of a corresponding hole in the other plate. The corresponding holes operate in use on the same beam or group of beams in the multi-beam. A suitable example of a type of lens for each element in the array is a two electrode decelerating lens. Additional electrodes can be provided. The bottom electrode of objective lens is a CMOS chip detector integrated into a multi-beam manipulator array. Integration of a detector array into the objective lens replaces a secondary column. The detector array, e.g., the CMOS chip, is preferably orientated to face a sample (because of the small distance (e.g., 100 μm) between wafer and bottom of the electron-optical system). In some embodiments, electrodes to capture the secondary electron signals are formed in the top metal layer of the CMOS device. The electrodes can be formed in other layers. Power and control signals of the CMOS may be connected to the CMOS by through-silicon vias. For robustness, preferably the bottom electrode consists of two elements: the CMOS chip and a passive Si plate with holes. The plate shields the CMOS from high E-fields.

In order to maximize the detection efficiency, it is desirable to make the electrode surface as large as possible, so that substantially all the area of the array objective lens (excepting the apertures) is occupied by electrodes and each electrode has a diameter substantially equal to the array pitch. In some embodiments, the outer shape of the electrode is a circle, but this can be made a square to maximize the detection area. Also, the diameter of the through-substrate hole can be minimized. Typical size of the electron beam is in the order of 5 to 15 micron.

In some embodiments, a single electrode surrounds each aperture. In some embodiments, a plurality of electrode elements are provided around each aperture. The electrons captured by the electrode elements surrounding one aperture may be combined into a single signal or used to generate independent signals. The electrode elements may be divided radially (i.e., to form a plurality of concentric annuluses), angularly (i.e., to form a plurality of sector-like pieces), both radially and angularly or in any other convenient manner.

However, a larger electrode surface leads to a larger parasitic capacitance, so a lower bandwidth. For this reason, it may be desirable to limit the outer diameter of the electrode. Especially in case a larger electrode gives only a slightly larger detection efficiency, but a significantly larger capacitance. A circular (annular) electrode may provide a good compromise between collection efficiency and parasitic capacitance.

A larger outer diameter of the electrode may also lead to a larger crosstalk (sensitivity to the signal of a neighboring hole). This can also be a reason to make the electrode outer diameter smaller. Especially in case a larger electrode gives only a slightly larger detection efficiency, but a significantly larger crosstalk.

The back-scattered and/or secondary electron current collected by electrode is amplified by a Trans Impedance Amplifier.

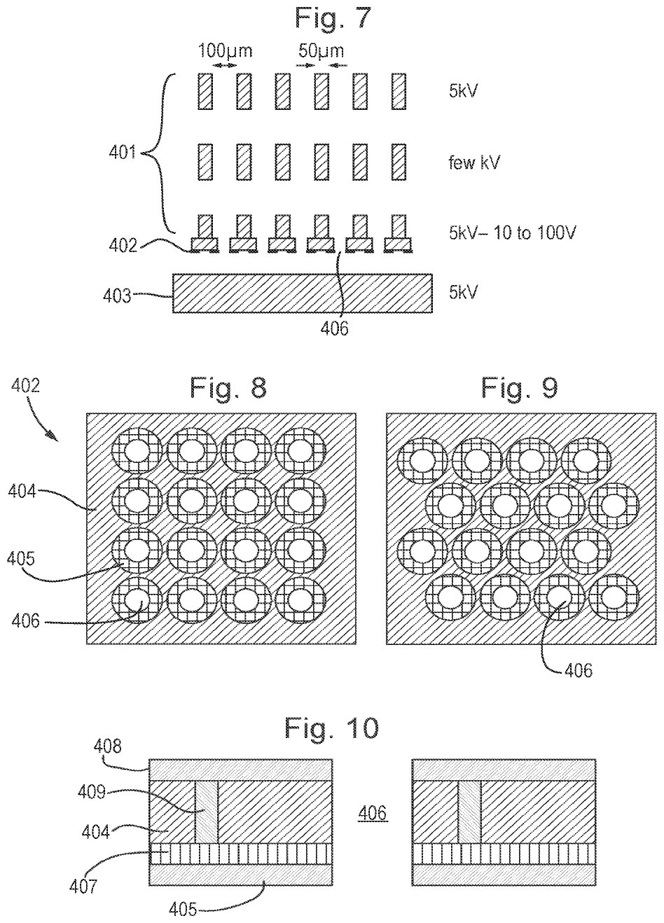

An example is shown in FIG. 7, which illustrates a multi-beam objective lens 401 in schematic cross section. On the output side of the objective lens 401, the side facing the sample 403, a detector module 402 is provided. FIG. 8 is a bottom view of detector module 402 which comprises a substrate 404 on which are provided a plurality of capture electrodes 405 each surrounding a beam aperture 406. The beam apertures 406 may be formed by etching through substrate 404. In the arrangement shown in FIG. 8, the beam apertures 406 are shown in a rectangular array. The beam apertures 406 can also be differently arranged, e.g., in a hexagonal close packed array as depicted in FIG. 9.

FIG. 10 depicts at a larger scale a part of the detector module 402 in cross section. Capture electrodes 405 form the bottommost, i.e., most close to the sample, surface of the detector module 402. Between the capture electrodes 405 and the main body of the silicon substrate 404 a logic layer 407 is provided. Logic layer 407 may include amplifiers, e.g., Trans Impedance Amplifiers, analogue to digital converters, and readout logic. In some embodiments, there is one amplifier and one analogue to digital converter per capture electrode 405. Logic layer 407 and capture electrodes 405 can be manufactured using a CMOS process with the capture electrodes 405 forming the final metallisation layer.

A wiring layer 408 is provided on the backside of substrate 404 and connected to the logic layer 407 by through-silicon vias 409. The number of through-silicon vias 409 need not be the same as the number of beam apertures 406. In particular if the electrode signals are digitized in the logic layer 407 only a small number of through-silicon vias may be required to provide a data bus. Wiring layer 408 can include control lines, data lines and power lines. It will be noted that in spite of the beam apertures 406 there is ample space for all necessary connections. The detection module 402 can also be fabricated using bipolar or other manufacturing techniques. A printed circuit board and/or other semiconductor chips may be provided on the backside of detector module 402.

The integrated detector array described above is particularly advantageous when used with a tool having tunable landing energy as secondary electron capture can be optimized for a range of landing energies.

It is desirable to increase the rate (area per unit time) at which a sample can be assessed or inspected. In a tool using charged-particle beams, it is not generally possible to increase speed of operation by increasing the beam intensity because of limitations on source brightness and total emission current. Increase beam current can also increase stochastic effects due to the mutual repulsion of the charged particles.

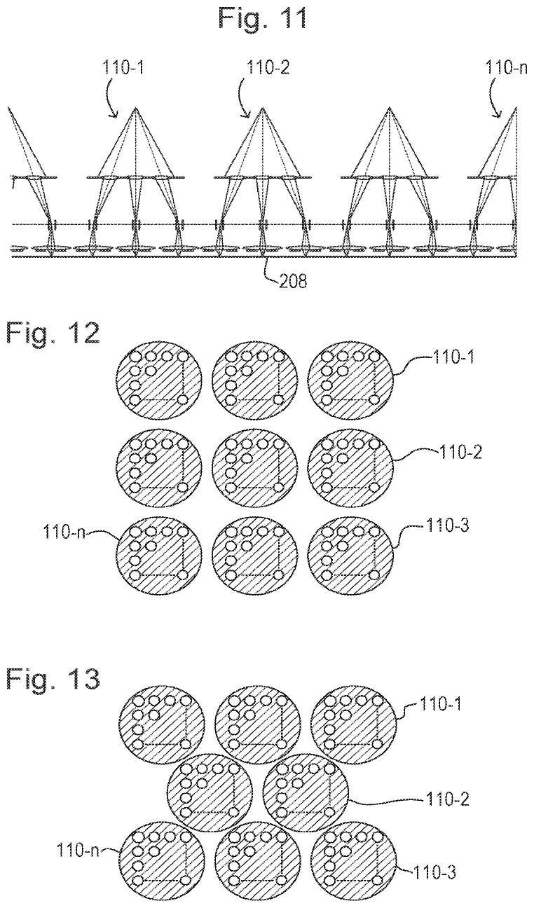

As shown in FIGS. 11 to 13, it is proposed to provide a tool that comprises a plurality of multi-beam columns 110-1 to 110-n, adjacent each other so as to project charged-particle beams onto the same sample. Each multi-beam column 110 comprises a projection apparatus 230 as described above. The term “multi-beam column” is used herein to denote a beam column that directs a plurality of electron beams onto a sample simultaneously. An increased area of the sample can thereby be assessed at one go. To minimize the spacing between columns, it is desirable that the condenser lenses and/or objective lenses are formed as MEMS or CMOS devices. If collimators are present, it is desirable that the collimators are also formed as MEMS or CMOS devices. The collimators may be deflectors and may referred to as collimator deflectors. The multi-beam columns 110-1 to 110-n can be arranged in a rectangular array as shown in FIG. 12 or a hexagonal array as shown in FIG. 13.

As mentioned above, each sub-beam of a multi-beam column 110 can be scanned across a respective individual scanning area of the object plane in which the sample is placed, which can be referred to as the sub-beam addressable area. The sub-beam addressable areas of all sub-beams of a multi-beam column 110 can be collectively referred to as the column-addressable area. The column-addressable area is not contiguous because the scanning range of the sub-beams is less than the pitch of the objective lenses. A contiguous region of the sample can be scanned by mechanically scanning the sample through the object plane. The mechanical scan of the sample can be a meander or step-and-scan type movement.

A contiguous area encompassing the column-addressable area is referred to herein as a region. A region can be a circle or polygon. The region is the smallest such shape that encompasses the column-addressable area. Regions addressed by adjacent multi-beam columns 110 are adjacent on the sample when placed in the object plane. Adjacent regions do not necessarily abut. The multi-beam columns 110 may be arranged to cover at least a portion to all of the sample. The regions may be spaced apart so that a full portion can be projected onto by the multi-beam columns 110. The stage may move relative to the multi-beam columns 110 so that the regions associated with the columns cover the full portion of the sample preferably without overlap. The footprint of a multi-beam column 110 (i.e., the projection of the multi-beam column 110 onto the object plane) is likely larger than the region into which the multi-beam column 110 projects sub-beams.

In some embodiments, focus correctors to correct the focus of individual beams or groups of beams on the sample, so as to account for any unflatness in the sample, are provided. Focus correctors may be electrostatic and/or mechanical. A focus correction can include any or all of corrections in the Z, Rx and Ry directions. A mechanical focus corrector can include actuators configured to tilt and/or shift an entire column or just part of it, e.g., the objective lens array. Focus correctors are described further below.

In some embodiments, the objective lenses have astigmatism correctors. The astigmatism correctors can be combined with focus correctors.

In some embodiments, the charged particle assessment tool further comprises one or more aberration correctors that reduce one or more aberrations in the sub-beams. In some embodiments, each of at least a subset of the aberration correctors is positioned in, or directly adjacent to, a respective one of the intermediate foci (e.g., in or adjacent to the intermediate image plane 233, 235 or focus points). The sub-beams have the smallest sectional area in or near a focal plane such as the intermediate plane. This provides more space for aberration correctors than is available elsewhere, i.e., upbeam or downbeam of the intermediate plane (or than would be available in alternative arrangements that do not have an intermediate image plane).

In some embodiments, aberration correctors positioned in, or directly adjacent to, the intermediate foci (or intermediate image plane) comprise deflectors to correct for the source 201 appearing to be at different positions for different beams. Correctors can be used to correct macroscopic aberrations resulting from the source that prevent a good alignment between each sub-beam and a corresponding objective lens.

The aberration correctors may correct aberrations that prevent a proper column alignment. Such aberrations may also lead to a misalignment between the sub-beams and the correctors. For this reason, it may be desirable to additionally or alternatively position aberration correctors at or near the condenser lenses 231 (e.g., with each such aberration corrector being integrated with, or directly adjacent to, one or more of the condenser lenses 231). This is desirable because at or near the condenser lenses 231 aberrations will not yet have led to a shift of corresponding sub-beams because the condenser lenses 231 are vertically close or coincident with the beam apertures. A challenge with positioning correctors at or near the condenser lenses 231, however, is that the sub-beams each have relatively large sectional areas and relatively small pitch at this location, relative to locations further downstream.

In some embodiments, each of at least a subset of the aberration correctors is integrated with, or directly adjacent to, one or more of the objective lenses 234. In some embodiments, these aberration correctors reduce one or more of the following: field curvature; focus error; and astigmatism. Additionally or alternatively, one or more scanning deflectors (not shown) may be integrated with, or directly adjacent to, one or more of the objective lenses 234 for scanning the sub-beams 211, 212, 214 over the sample 208. In some embodiments, the scanning deflectors may be used as described in EP2425444A1 (hereby incorporated by reference in its entirety, and in particular to the disclosure of the use of an aperture array as a scanning deflector).

The aberration correctors may be CMOS based individual programmable deflectors as disclosed in EP2702595A1 or an array of multipole deflectors as disclosed in EP2715768A2, of which the descriptions of the beamlet manipulators in both documents are hereby incorporated by reference.

In some embodiments, such as shown in FIG. 3. aberration correctors, for example the aberration correctors 126 associated with the objective lenses 234, comprise field curvature correctors that reduce field curvature. Reducing field curvature reduces errors caused by field curvature, such as astigmatism and focus error. In the absence of correction, significant field curvature aberration effects are expected to occur at the objective lenses 234 in embodiments where the sub-beams 211, 212, 213 propagate along straight-line paths between the condenser lenses 231 and the objective lenses 234 due to the resulting oblique angles of incidence onto the objective lenses 234. Field curvature effects could be reduced or removed by collimating the sub-beams 211, 212, 213 before the sub-beams 211, 212, 213 reach the objective lenses 234. However, the provision of collimators upstream of the objective lenses 234 would add complexity, as related in the example shown in FIG. 4. The field curvature correctors make it possible to avoid collimators and thereby reduce complexity. As mentioned above, the absence of collimators upstream of the objective lenses 234 may additionally allow the beam current to be increased by allowing the objective lenses to be provided at a larger pitch.

In some embodiments, the field curvature correctors are integrated with, or directly adjacent to, one or more of the objective lenses 234. In some embodiments, the field curvature correctors comprise passive correctors. Passive correctors could be implemented, for example, by varying the diameter and/or ellipticity of apertures of the objective lenses 118. The passive correctors may be implemented for example as described in EP2575143A1 hereby incorporated by reference in particular to the disclosed use of aperture patterns to correct astigmatism. The passive nature of passive correctors is desirable because it means that no controlling voltages are required. In embodiments where the passive correctors are implemented by varying the diameter and/or ellipticity of apertures of the objective lenses 118, the passive correctors provide the further desirable feature of not requiring any additional elements, such as additional lens elements. A challenge with passive correctors is that they are fixed, so the required correction needs to be carefully calculated in advance. Additionally or alternatively, in some embodiments, the field curvature correctors comprise active correctors. The active correctors may controllably correct charged particles to provide the correction. The correction applied by each active corrector may be controlled by controlling the potential of each of one or more electrodes of the active corrector. In some embodiments, passive correctors apply a coarse correction and active correctors apply a finer and/or tunable correction.

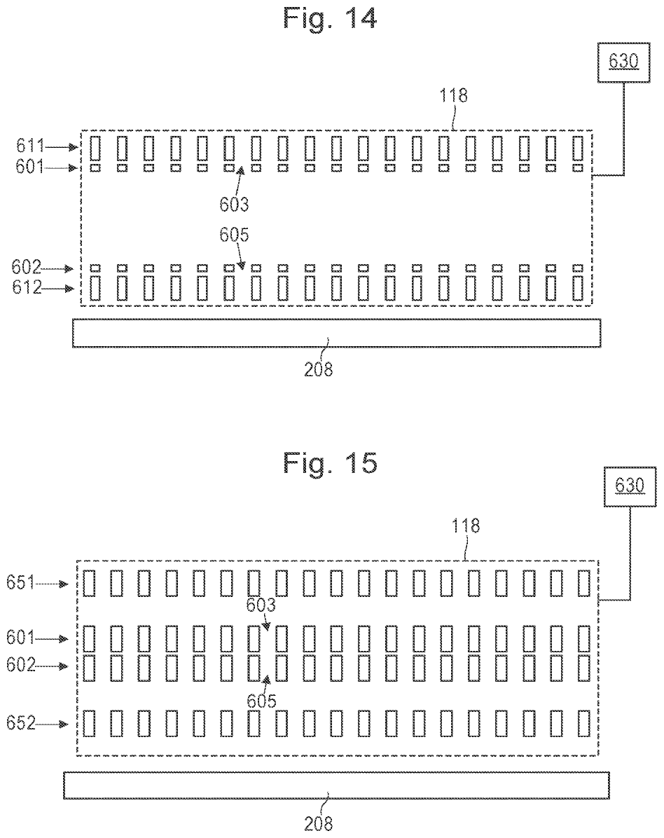

In some embodiments, as exemplified in FIGS. 14 to 20, the charged-particle multi-beam column array comprises a focus corrector. The focus corrector may be configured to apply focus corrections to each individual sub-beam. In other embodiments, the focus corrector applies a group focus correction to each of a plurality of groups of sub-beams of the multi-beams. A focus correction can include any or all of corrections in the Z, Rx and Ry directions. Each group focus correction is the same for all of the sub-beams of the respective group. As mentioned above, applying corrections in groups may reduce routing requirements. In some embodiments, the focus corrector applies different corrections to sub-beams from different multi-beams. Thus, a focus correction applied to a multi-beam from one multi-beam column 110 may be different to a focus correction applied to a multi-beam from a different multi-beam column 110 in the same array. The focus corrector is thus able to correct for manufacturing or installation differences between different multi-beam columns 110 and/or differences in the height of the surface of the sample 208 between different multi-beam columns 110. Alternatively or additionally, the focus corrector may apply different corrections to different sub-beams within the same multi-beam. Thus, the focus corrector may be able to provide focus corrections at a finer level of granularity, thereby correcting for example for manufacturing variations within a multi-beam column 110 and/or for relatively short-range variations in the height of the surface of the sample 208.

In some embodiments, the focus corrector comprises a mechanical actuator 630. The mechanical actuator 630 applies each of one or more of the group focus corrections at least partly by mechanical actuation of a focus adjusting element. Mechanical actuation of the focus adjusting element may apply a tilt and/or shift of an entire multi-beam column 110 or just part of it, e.g., the objective lens array 118. For example, the focus adjusting element may comprise one or more electrodes of an objective lens array 118 and the mechanical actuator 630 may adjust the focus by moving one or more (e.g., all) electrodes of the objective lens array 118 (e.g., towards or away from the surface of the sample 208).

In some embodiments, the focus corrector applies each of one or more of the group focus corrections at least partly by changing an electrical potential applied to each of one or more electrodes. In some embodiments, as exemplified in FIGS. 14 to 20, the focus corrector comprises at least one corrector aperture array 601, 602. The corrector aperture array 601 defines a plurality of groups of corrector apertures 603 (each group containing a plurality of the corrector apertures 603). The corrector aperture array 601 may be integrated with, and/or directly adjacent to, an objective lens array 118. For example, the corrector aperture array 601 may be formed on an electrode (e.g., a body defining apertures) of the objective lens array 118.

In the example shown in FIG. 14, the corrector aperture array 601 is formed on an up-beam electrode 611 of a two-electrode objective lens array 118. In the example shown in FIG. 14, a further corrector aperture array 602 is formed on a down-beam electrode 612 of the objective lens array 118. The further corrector aperture array 602 may define a further plurality of groups of corrector apertures 605.

In the example shown in FIG. 15, the corrector aperture array 601 is formed on (or forms) an up-beam surface of a central electrode of a three-electrode objective lens array 118. In the example shown in FIG. 15, a further corrector aperture array 602, defining a further plurality of groups of corrector apertures 605, is formed on (or forms) a down-beam surface of the central electrode. Potential differences between the corrector aperture array 601 and the corrector aperture array 602 can be small enough to avoid any significant lensing effect in the region between the two corrector aperture arrays 601, 602. The three-electrode objective lens array 118 may be configured to operate as an Einzel lens array.

The at least one corrector aperture array 601, 602 may be formed on (or may form) any surface of any electrode in an objective lens array. It is desirable to provide the at least one corrector aperture array 601, 602 on an electrode having a stronger lensing effect than other electrodes in the objective lens array. This allows the at least one corrector aperture array 601, 602 to have the strongest effect for a given applied potential difference. In the arrangement of FIG. 15, the central electrode will typically have a stronger lensing effect than the up-beam electrode 651 and the down-beam electrode 652, so the two corrector aperture arrays 601, 602 are associated with the central electrode.

Each corrector aperture array 601, 602 comprises a respective electrode system 621, 622. Each electrode system 621, 622 comprises a plurality of electrodes. Each electrode applies a common electrical potential to aperture perimeter surfaces of all apertures in a different one of the groups of corrector apertures. Each electrode in each electrode system 621, 622 is electrically isolated from each other electrode in the electrode system 621, 622. Each electrode is electrically connected simultaneously to aperture perimeter surfaces of all apertures in a different one of the groups of corrector apertures 603, 605. Each corrector aperture 603, 605 is aligned along a sub-beam path with a respective objective lens in the objective lens array 118. In the example of FIGS. 14 and 15, each objective lens in the objective lens array 118 is defined by apertures in electrodes that are aligned with each other along a respective sub-beam path. Each corrector aperture 603, 605 may thus be aligned with apertures in up-beam and down-beam electrodes that are aligned with each other along a respective sub-beam path.

In some embodiments, in each of one or more of the groups of corrector apertures 603, 605, the objective lenses with which the corrector apertures 603, 605 are aligned are all in the same multi-beam column 110. Alternatively or additionally, in some embodiments, in each of one or more of the groups of corrector apertures 603, 605, at least a subset of the objective lenses with which the corrector apertures 603, 605 are aligned are in different multi-beam columns 110. The corrector aperture array 603 (and/or any further aperture array 605 provided) may use its respective plurality of electrodes to correct focus errors. The corrections are applied by using the electrodes to control an electric field in regions through which the sub-beams pass.

Within each corrector aperture array 601, 602, each electrode is capable of applying an electrical potential simultaneously to plural corrector apertures 603, 605 independently of the potential applied to other apertures in the corrector aperture array 601, 602. Fewer electrodes are therefore needed than would be the case if each electrode were connected to one corrector aperture only. Having fewer electrodes facilitates routing of the electrodes, thereby facilitating manufacture and optionally enabling a denser pattern of corrector apertures in the electrode. Controlling the potentials applied to groups of corrector apertures 603, 605 independently provides a greater level of control than if all of the corrector apertures were connected together electrically, such as when the corrector apertures are formed in an integral metallic plate. An improved balance of ease of manufacture and controllability of sub-beam manipulation is therefore provided.

In some embodiments, the electrode systems 621, 622 are each provided as a conductive layer or structure on a support structure. The electrode systems 621, 622 may be formed using a silicon-on-insulator process. The electrode systems 621, 622 may be provided as a conductive layer or structure on an insulating layer of silicon oxide. The electrode systems 621, 622 may comprise a metalized layer and/or a conductive semiconductor such as silicon or doped silicon. The electrode systems 621, 622 may comprise a metal, such as molybdenum or aluminum.

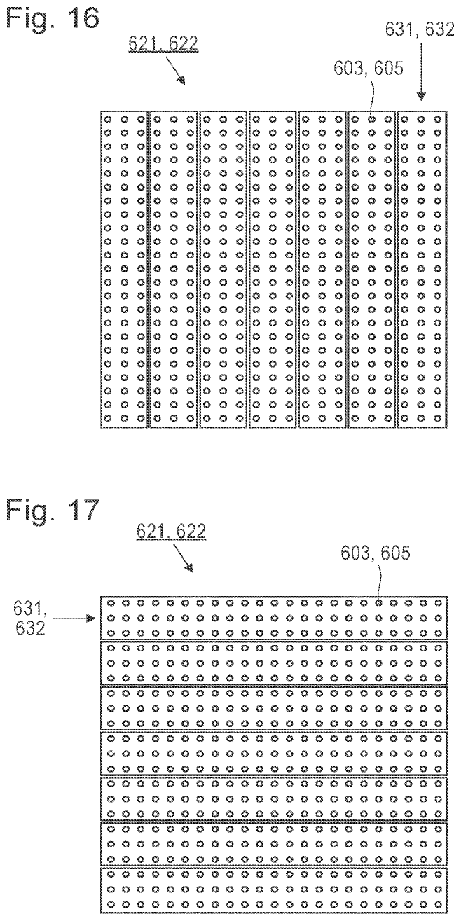

In some embodiments, as exemplified in FIGS. 16 to 19, each electrode in each of one or more of the electrode systems 621, 622 comprises an elongate conductive strip 631, 632. The respective elongate conductive strips 631, 632 in each electrode system may be implemented as a series of parallel plates for example. The conductive strips 631, 632 of each respective electrode system 621, 622 are preferably parallel to each other and/or substantially linear. Arranging the electrodes in conductive strips 631, 632 in the respective electrode system 621, 622 makes routing easier because electrical connections to the conductive strips 631, 632 can be made at the ends of the conductive strips 631, 632. In some arrangements, the conductive strips 631, 632 are arranged to extend to peripheral edges of the respective electrode system 621, 622, as shown schematically in FIGS. 16 to 19. Extending the conductive strips 631, 632 to the peripheral edges means that electrical connections to the conductive strips 631, 632 can be made at the peripheral edges. The peripheral edges of the electrode systems 621, 622 shown in the Figures are schematic. The shape and relative size of the peripheral surfaces may be different in practical arrangements. The peripheral surfaces may be dimensioned, for example, to contain many more of the corrector apertures 603, 605 than shown in the Figures.

In some embodiments, the corrector apertures 603, 605 are arranged in a regular array. The regular array has a repeating unit cell. The regular array may comprise a square array, rectangular array, or hexagonal array, for example. The corrector apertures 603, 605 may alternatively be arranged in an irregular arrangement comprising a plurality of the apertures 603, 605, which may be referred to as an irregular array. In arrangements having a regular array, the conductive strips 631, 632 may be made parallel to each other and perpendicular to a principal axis of the array. In the examples shown in FIGS. 14 to 20, the corrector apertures 603, 605 are arranged in a square array. The regular array may have one principal axis being horizontal in the plane of the page and another principal axis being vertical in the plane of the page. The conductive strips 631, 632 in FIGS. 16 and 24 are thus parallel to each other and perpendicular to the horizontal principal axis. The conductive strips 631, 632 in FIGS. 17 and 19 are parallel to each other and perpendicular to the vertical principal axis.

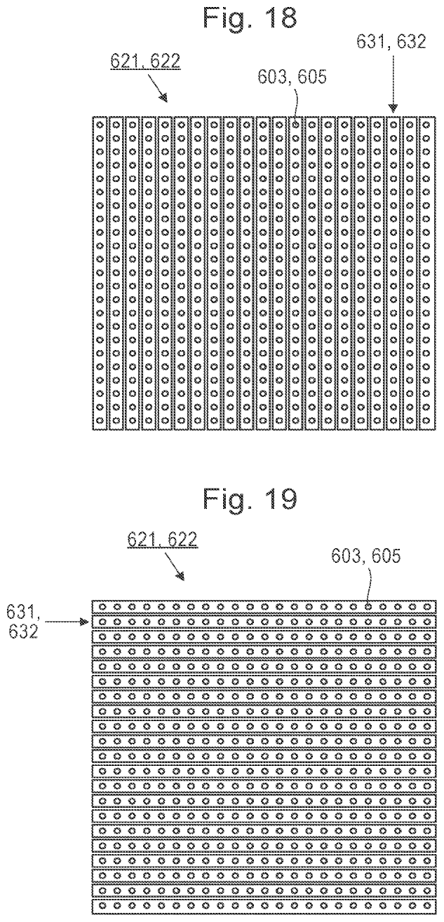

The conductive strips 631, 632 may each have a short axis and a long axis. In the example of FIGS. 16 and 18, each short axis is horizontal, and each long axis is vertical. In the example of FIGS. 17 and 19, each short axis is vertical, and each long axis is horizontal. A pitch of the conductive strips 631, 632 parallel to the short axis may be larger than a pitch of the array parallel to the short axis. Each vertical conductive strip may therefore comprise multiple columns of apertures 603, 605 and/or each horizontal strip may therefore comprise multiple rows of apertures 603, 605. This approach provides a good balance between controllability and ease of manufacture. Alternatively, a pitch of the conductive strips 631, 632 parallel to the short axis may be equal to the pitch of the array parallel to the short axis, which provides finer spatial control of the electrical field.

In some embodiments, plural corrector aperture arrays 601, 602 are provided. The corrector aperture arrays 601, 602 may be aligned with each other along sub-beam paths. In some embodiments, conductive strips 631 in the electrode system 621 of one of the corrector aperture arrays 601 are non-parallel with, e.g., perpendicular to, conductive strips 632 in the electrode system 621 of a different one of the corrector aperture arrays 602. This arrangement may be particularly preferable, for example, where the conductive strips 631, 632 are parallel to each other in each of the electrode systems 621, 622. For example, the electrode system 621 of one of the corrector aperture arrays 601 may comprise conductive strips 631 as shown in FIG. 16 or 18 and the electrode system 622 of a different one of the corrector aperture arrays 602 may comprise conductive strips 632 as shown in FIG. 17 or 19 or vice versa. Crossing the conductive strips 631, 632 in different electrode systems 621, 622 in this way provides a wide range of possible combinations of potential difference between corresponding apertures 603, 605 in the respective corrector aperture arrays without making routing of electrical connections to the respective conductive strips 631, 632 more difficult.

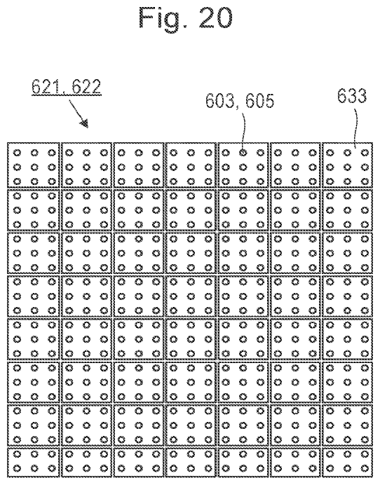

In a further arrangement, as exemplified in FIG. 20, the plurality of electrodes of an electrode system 621, 622 comprises a plurality of conductive elements 633 that tessellate with each other. In the example shown, the conductive elements 633 are square. Other tessellating shapes may be used, such as rectangles, rhomboids, parallelograms, and hexagons and/or repeating groups of shapes that tessellate. This approach may provide more degrees of freedom for manipulating charged particles in comparison to arrangements using conductive strips as discussed above with reference to FIGS. 16 to 19, but routing of electrical signals to the individual electrodes may be more complex

In some embodiments, the beam columns are arranged in a rectangular array.

In some embodiments, the beam columns are arranged in a hexagonal array.

In some embodiments, the number of beam columns is in the range of from 9 to 200.

In some embodiments, the number of condenser lens in each beam column is in the range of from 1,000 to 100,000, desirably from 5,000 to 25,000.

In some embodiments, the condenser lenses of each beam column are arranged in a respective array having a pitch in the range of from 50 to 500 μm, desirably in the range of from 70 to 150 μm.

In some embodiments, the condenser lenses and/or the objective lenses are formed as MEMS or CMOS devices.

In some embodiments, one or more aberration correctors configured to reduce one or more aberrations in the sub-beams are provided.

In some embodiments, each of at least a subset of the aberration correctors is positioned in, or directly adjacent to, a respective one of the intermediate foci.

In some embodiments, one or more scanning deflectors for scanning the sub-beams over the sample are provided.

In some embodiments, the one or more scanning deflectors are integrated with, or are directly adjacent to, one or more of the objective lenses.

In some embodiments, the assessment tool comprises one or more collimators. The one or more collimators is one or more collimator deflectors.

In some embodiments, the one or more collimator deflectors are configured to bend a respective beamlet by an amount effective to ensure that the principal ray of the sub-beam is incident on the sample substantially normally.

In some embodiments, detectors integrated into the objective lenses are provided.

An assessment tool according to some embodiments of the present disclosure may be a tool which makes a qualitative assessment of a sample (e.g., pass/fail), one which makes a quantitative measurement (e.g., the size of a feature) of a sample or which generates an image of map of a sample. Examples of assessment tools are inspection tools and metrology tools.

The term ‘adjacent’ may include the meaning ‘abut’.

The embodiments herein described may take the form of a series of aperture arrays or electron-optical elements arranged in arrays along a beam or a multi-beam path. Such electron-optical elements may be electrostatic. In some embodiments, all the electron-optical elements, for example from the beam limiting aperture array to the last electron-optical element in a sub-beam path before a sample, may be electro static and/or may be in the form of an aperture array or a plate array. In arrangement one or more of the electron-optical element may be manufactured as a microelectromechanical system (MEMS).

While the embodiments of the present disclosure have been described in connection with various examples, other embodiments will be apparent to those skilled in the art from consideration of the specification and practice of the technology disclosed herein. It is intended that the specification and examples be considered as exemplary only, with a true scope and spirit being indicated by the following claims and clauses

Clause 1: A charged-particle assessment tool comprising: a plurality of beam columns, each beam column comprising: a charged-particle beam source configured to emit charged particles; a plurality of condenser lenses configured to form charged particles emitted from the charged-particle beam source into a plurality of charged-particle beams; and a plurality of objective lenses, each configured to project one of the plurality of charged-particle beams onto a sample; wherein: the beam columns are arranged adjacent one-another so as to project the charged particle beams onto adjacent regions of the sample. The condenser lenses may be configured to focus the plurality of charged particle beams to a respective intermediate focus. The plurality of objective lenses may be configured to be down beam of the intermediate focuses are a plurality of objective lenses. Aberration correctors may be configured to reduce one or more aberrations in the plurality of charged particle beams. The aberration correctors may comprise astigmatism correctors, focus correctors and/or field curvature correctors

Clause 2: A tool according to clause 1 further comprising focus correctors.

Clause 3: A tool according to clause 1 or 2 wherein the objective lenses have or comprise astigmatism correctors.

Clause 4: A tool according to clause 1, 2 or 3 wherein the beam columns are arranged in a rectangular array.

Clause 5: A tool according to clause 1, 2 or 3 wherein the beam columns are arranged in a hexagonal array.

Clause 6: A tool according to any one of the preceding clauses wherein the number of beam columns is in the range of from 9 to 200.

Clause 7: A tool according to any one of the preceding clauses wherein the number of condenser lens in each beam column is in the range of from 1,000 to 100,000, desirably from 5,000 to 25,000.

Clause 8: A tool according to any one of the preceding clauses wherein the condenser lenses of each beam column are arranged in a respective array having a pitch in the range of from 50 to 500 μm, desirably in the range of from 70 to 150 μm.

Clause 9: A tool according to any one of the preceding clauses wherein the condenser lenses and/or the objective lenses are formed as MEMS or CMOS devices.

Clause 10: A tool according to any one of the preceding clauses further comprising one or more aberration correctors configured to reduce one or more aberrations in the sub-beams.

Clause 11: A tool according to clause 9, wherein each of at least a subset of the aberration correctors is positioned in, or directly adjacent to, a respective one of the intermediate foci.

Clause 12: A tool according to any of the preceding clauses further comprising one or more scanning deflectors for scanning the sub-beams over the sample and optionally the one or more scanning deflectors are integrated with, or are directly adjacent to, one or more of the objective lenses.

Clause 13: A tool according to any of the preceding clause, further comprising one or more collimators, wherein the or one of the collimators is provided at a respective one or more intermediate foci and preferably the collimator is one or more collimator deflectors and optionally the one or more collimator deflectors are configured to bend a respective beamlet by an amount effective to ensure that the principal ray of the sub-beam is incident on the sample substantially normally.

Clause 14: A tool according to any one of the preceding clauses further comprising detectors integrated into the objective lenses, and preferably the detectors face towards the sample.

Clause 15: An inspection method comprising: using a plurality of beam columns to emit charged-particle beams toward a sample, each beam column comprising: a charged-particle beam source configured to emit charged particles; a plurality of condenser lenses configured to form charged particles emitted from the charged-particle beam source into a plurality of charged-particle beams; and a plurality of objective lenses, each configured to project one of the plurality of charged-particle beams onto the sample; wherein: the beam columns are arranged adjacent one-another so as to project the charged particle beams onto adjacent regions of the sample. The condenser lenses may be configured to focus the plurality of charged particle beams to a respective intermediate focus. The plurality of objective lenses may be configured to be down beam of the intermediate focuses are a plurality of objective lenses. Aberration correctors may be configured to reduce one or more aberrations in the plurality of charged particle beams.

Clause 16: A charged-particle multi-beam column array for a charged-particle tool for projecting a plurality of charged-particle multi-beams towards a sample, the charged-particle multi-beam column array comprising: a plurality of charged-particle multi-beam columns configured to project respective multi-beams simultaneously onto different regions of the sample; and a focus corrector configured to apply a group focus correction to each of a plurality of groups of sub-beams of the multi-beams, each group focus correction being the same for all of the sub-beams of the respective group.

Clause 17: The multi-beam column array of clause 16, wherein the focus corrector is configured to apply different corrections to sub-beams from different multi-beams.

Clause 18: The multi-beam column array of clause 16 or 17, wherein the focus corrector is configured to apply different corrections to different sub-beams within the same multi-beam.

Clause 19: The multi-beam column array of any of clauses 16 to 18, wherein the focus corrector is configured to apply each of one or more of the group focus corrections at least partly by mechanical actuation of a focus adjusting element.

Clause 20: The multi-beam column array of any of clauses 16 to 19, wherein the focus corrector is configured to apply each of one or more of the group focus corrections at least partly by changing an electrical potential applied to each of one or more electrodes.

Clause 21: The multi-beam column array of clause 20, wherein: each multi-beam column comprises a sub-beam defining aperture array configured to form sub-beams from a beam of charged particles emitted by a source associated with the multi-beam column and an objective lens array, each objective lens being configured to project a sub-beam onto a sample; the focus corrector comprises a corrector aperture array in which is defined a plurality of groups of corrector apertures; and the corrector aperture array is integrated with, and/or directly adjacent to, one or more of the objective lens arrays.

Clause 22: The multi-beam column array of clause 21, wherein the sub-beam defining aperture array is adjacent the objective lens array along paths of the sub-beams.

Clause 23: The multi-beam column array of clause 21 or 22, wherein the corrector aperture array comprises an electrode system comprising a plurality of electrodes, each electrode being electrically isolated from each other electrode and electrically connected simultaneously to aperture perimeter surfaces of all apertures in a different one of the groups of corrector apertures.

Clause 24: The multi-beam column array of any of clauses 21 to 23, wherein the corrector aperture array comprises an electrode system comprising a plurality of electrodes, each electrode being configured to apply a common electrical potential to aperture perimeter surfaces of all apertures in a different one of the groups of corrector apertures.

Clause 25: The multi-beam column array of any of clauses 21 to 24, wherein each corrector aperture is aligned along a sub-beam path with a respective objective lens.

Clause 26: The multi-beam column array of clause 25, wherein in each of one or more of the groups of corrector apertures, the objective lenses with which the corrector apertures are aligned are all in the same multi-beam column.

Clause 27: The multi-beam column array of clause 25 or 26, wherein in each of one or more of the groups of corrector apertures, at least a subset of the objective lenses with which the corrector apertures are aligned are in different multi-beam columns.

Clause 28: The multi-beam column of any of clauses 16 to 27, wherein each column further comprises at least one of: a plurality of condenser lenses configured to form from the plurality of charged-particle beams from the charged particles emitted from the charged-particle beam source; a collimator at a respective one or more intermediate foci; astigmatism correctors associated with the objective lenses; one or more aberration correctors configured to reduce one or more aberrations in the sub-beams, wherein preferably each of at least a subset of the aberration correctors is positioned in, or directly adjacent to, a respective one of the intermediate foci; one or more scanning deflectors for scanning the sub-beams over the sample and optionally the one or more scanning deflectors are integrated with, or are directly adjacent to, one or more of the objective lenses; and detectors preferably integrated into the objective lenses.

Clause 29: An inspection method, comprising: using a multi-beam column array to project plural charged-particle multi-beams towards a sample; and applying a group focus correction to each of a plurality of groups of sub-beams of the multi-beams, each group focus correction being the same for all of the sub-beams of the respective group.

Clause 30: The method of clause 29, wherein the applying of the group focus correction comprises applying different corrections to sub-beams from different multi-beams.

Clause 31: The method of clause 29 or 30, wherein the applying of the group focus correction comprises applying different corrections to different sub-beams within the same multi-beam.

Clause 32: The method of any of clauses 29 to 31, wherein the group focus correction is applied mechanically and/or electrostatically.

Clause 33: An inspection method, comprising using the multi-beam column array of any of clauses 1 to 28 to project plural charged-particle multi-beams towards a sample and detecting charged particles emitted from the sample.

1. A charged-particle assessment tool comprising:
a plurality of beam columns, each beam column comprising: a charged-particle beam source configured to emit charged particles; a plurality of condenser lenses configured to form charged particles emitted from the charged-particle beam source into a plurality of charged-particle beams, the condenser lenses configured to focus the plurality of charged particle beams to a respective intermediate focus; a plurality of objective lenses configured to be down beam of the intermediate focuses are a plurality of objective lenses, each objective lens configured to project one of the plurality of charged-particle beams onto a sample; and aberration correctors configured to reduce one or more aberrations in the plurality of charged particle beams, wherein:
the beam columns are arranged adjacent one-another so as to project the charged particle beams onto adjacent regions of the sample.

2. A tool according to claim 1 further comprising detectors integrated into the objective lenses and preferably the detectors face towards the sample.

3. A tool according to claim 1, wherein the aberration correctors comprise focus correctors.

4. A tool according to claim 1, the aberration correctors comprising astigmatism correctors and/or field curvature correctors, preferably wherein the objective lenses comprise the astigmatism correctors.

5. A tool according to claim 1 wherein the beam columns are arranged in a rectangular array.

6. A tool according to claim 1, wherein the beam columns are arranged in a hexagonal array.

7. A tool according to claim 1 wherein the number of beam columns is in the range of from 9 to 200.

8. A tool according to claim 1, wherein the number of condenser lens in each beam column is in the range of from 1,000 to 100,000.

9. A tool according to claim 1 wherein the condenser lenses of each beam column are arranged in a respective array having a pitch in the range of from 50 to 500 μm.

10. A tool according to claim 1 wherein the condenser lenses and/or the objective lenses are formed as MEMS or CMOS devices.

11. A tool according to claim 1, wherein each of at least a subset of the aberration correctors is positioned in, or directly adjacent to, a respective one of the intermediate foci.

12. A tool according to claim 1 further comprising one or more scanning deflectors for scanning the sub-beams over the sample and optionally the one or more scanning deflectors are integrated with, or are directly adjacent to, one or more of the objective lenses.

13. A tool according to claim 1, further comprising one or more collimators

14. A tool according to claim 13, wherein the one or more collimators is one or more collimator deflectors and optionally the one or more collimator deflectors are configured to bend a respective beamlet by an amount effective to ensure that the principal ray of the sub-beam is incident on the sample substantially normally.

15. An inspection method comprising:
using a plurality of beam columns to emit charged-particle beams toward a sample, each beam column comprising: a charged-particle beam source configured to emit charged particles; a plurality of condenser lenses configured to form charged particles emitted from the charged-particle beam source into a plurality of charged-particle beams and configured to focus the plurality of charged particle beams to a respective intermediate focus; a plurality of objective lenses, each configured to be down beam of the respective intermediate foci, each of the plurality of objective lenses configured to project one of the plurality of charged-particle beams onto the sample; and aberration correctors configured to reduce one or more aberrations in the plurality of charged particle beams; wherein:
the beam columns are arranged adjacent one-another so as to project the charged particle beams onto adjacent regions of the sample.

16. A charged-particle assessment tool comprising:
a plurality of beam columns, each beam column comprising:
a charged-particle beam source configured to emit charged particles;
a plurality of condenser lenses configured to form charged particles emitted from the charged-particle beam source into a plurality of charged-particle beams;
a plurality of objective lenses, each configured to project one of the plurality of charged-particle beams onto a sample; and
a detector configured to face the sample,
wherein: the beam columns are arranged adjacent one-another so as to project the charged particle beams onto adjacent regions of the sample.

17. A charged-particle assessment tool of claim 16 further comprising wherein aberration correctors configured to reduce one or more aberrations in the plurality of charged particle beams.

18. A charged-particle assessment tool of claim 17, wherein the aberration correctors comprise astigmatism correctors, focus correctors and/or field curvature correctors.

19. A charged-particle assessment tool of claim 16, wherein the condenser lenses are configured to focus the plurality of charged particle beams to a respective intermediate focus.

20. A charged-particle assessment tool of claim 19, wherein the plurality of objective lenses are configured to be down beam of the intermediate focuses.
